(19) United States
(12) Patent Application Publication
(10) Pub. No.: US 2012/0040533 A1
(43) Pub. Date: Feb. 16, 2012

(54) Method of Manufacturing Semiconductor Devices

(75) Inventor: Myung Kyu Ahn, Suwon-si (KR)

(73) Assignee: HYNIX SEMICONDUCTOR INC., Icheon-si (KR)

(21) Appl. No.: 12/972,092

(22) Filed: Dec. 17, 2010

(30) Foreign Application Priority Data
Aug. 10, 2010 (KR) 10-2010-0076827

(51) Int. Cl. H01L 21/311

(52) U.S. Cl. 438/694; 257/E21.249

(57) ABSTRACT

A method of manufacturing semiconductor devices comprises forming a plurality of patterns by patterning a thin film formed over an underlying layer and cleaning contaminants generated when the thin film is patterned using a plasma both having oxidative and reductive properties.

### CROSS-REFERENCE TO RELATED APPLICATION

Priority to Korean patent application number 10-2010-0076827 filed on Aug. 10, 2010, the entire disclosure of which is incorporated by reference herein, is claimed.

### BACKGROUND

An exemplary embodiment of the disclosure relates generally to a method of manufacturing semiconductor devices and, more particularly, to a method of manufacturing semiconductor devices that is capable of improving a phenomenon in which patterns collapse because of a cleaning process.

The patterns of a semiconductor device may be formed by a thin film deposition process and a thin film patterning process. The thin film patterning process is performed by removing an exposed thin film by etching using hard mask patterns or photoresist patterns as an etch mask. The hard mask patterns may be formed by removing an exposed hard mask layer using the photoresist patterns as an etch mask.

After the thin film patterning process is performed, the photoresist patterns are formed, or the hard mask patterns are formed, contaminants generated during the process may remain. To remove the contaminants, a cleaning process is typically performed after the thin film patterning process is performed, the photoresist patterns are formed, or the hard mask patterns are formed. In general, the cleaning process is performed using a wet method with a liquid cleaning agent.

FIGS. 1A and 1B are diagrams illustrating a known wet cleaning method.

Referring to FIG. 1A, a plurality of patterns 3 is formed over an underlying layer 1. The underlying layer 1 typically is a semiconductor substrate, an insulating layer, or a conductive layer. The plurality of patterns 3 are typically hard mask patterns, patterns constituting a semiconductor device, or photoresist patterns.

After the plurality of patterns 3 is formed, a wet cleaning process is performed using a liquid washing agent 7, such as deionized (DI) water, to remove contaminants.

Referring to FIG. 1B, in a process of discharging the cleaning agent used in the wet cleaning process, the plurality of patterns 3 may collapse because of the liquid cleaning agent's surface tension. In particular, the patterns 3 collapse more severely with an increase of the ratio of the patterns' 3 height H to the width W to increase the degree of integration of semiconductor devices. If the patterns 3 collapse in the process of manufacturing the semiconductor devices, there are problems in that the yield and reliability of semiconductor devices adversely affected.

### BRIEF SUMMARY

The disclosure provides a method of manufacturing semiconductor devices, which is capable of improving (i.e., reducing or eliminating) a phenomenon in which patterns collapse because of a cleaning process. Furthermore, the disclosure provides a method of manufacturing semiconductor devices, which is capable of improving cleaning efficiency.

A method of manufacturing semiconductor devices according to an aspect of the present disclosure comprises forming a plurality of patterns by forming a thin film over an underlying layer patterning the thin film whereby contaminants are generated, and cleaning the contaminants using a plasma having both oxidative and reductive properties.

H₂O plasma preferably is used as the plasma.

In cleaning the contaminants, one or more of O₂ gas, N₂ gas, and fluorine gas preferably is added to improve cleaning characteristics.

Patterning the thin film and cleaning the contaminants preferably are performed in-situ.

Cleaning the contaminants preferably is performed at a temperature in a range of 25° C. to 300° C.

The plasma preferably is generated using at least one of a capacitively coupled plasma (CCP) type plasma generation apparatus, an inductively coupled plasma (ICP) type plasma generation apparatus, and a microwave plasma type plasma generation apparatus.

### BRIEF DESCRIPTION OF THE DRAWINGS

FIGS. 1A and 1B are diagrams illustrating a known wet cleaning method; and

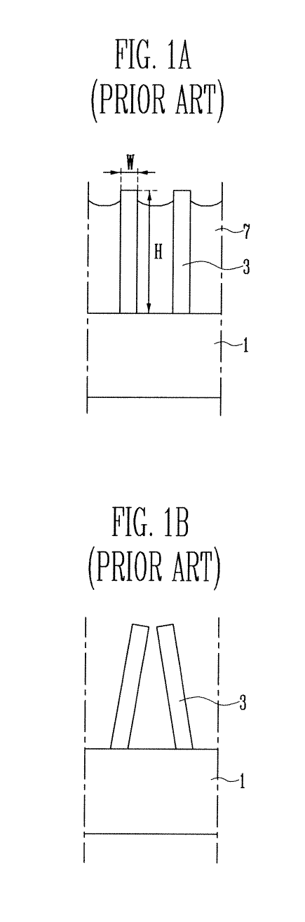

FIGS. 2A and 2B are diagrams illustrating a method of manufacturing semiconductor devices according to an exemplary embodiment of the disclosure.

### DESCRIPTION OF EMBODIMENT

Hereinafter, an exemplary embodiment of the disclosure is described in detail with reference to the accompanying drawings. The drawing figures are provided to allow those having ordinary skill in the art to understand the scope of the embodiment of the disclosure.

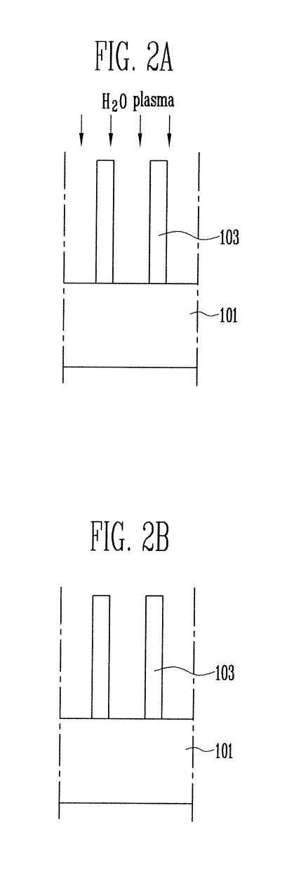

FIGS. 2A and 2B are diagrams illustrating a method of manufacturing semiconductor devices according to an exemplary embodiment of the disclosure.

Referring to FIG. 2A, a plurality of patterns 103 is formed over an underlying layer 101. The underlying layer 101 preferably is a semiconductor substrate, an insulating layer, or a conductive layer. The patterns 103 preferably are hard mask patterns, patterns constituting a semiconductor device, or photoresist patterns.

The patterns 103 preferably are formed by depositing a thin film for patterns over the underlying layer 101 and patterning the thin film. Where the thin film for patterns is a photoresist layer, the thin film preferably is patterned by a photolithography process including exposure and development processes. Where the thin film for patterns is a hard mask layer, the thin film preferably is patterned by an etch process, preferably using photoresist patterns as an etch mask. Furthermore, where the thin film for patterns is a thin film for the patterns of a semiconductor device, the thin film preferably is patterned by an etch process using photoresist patterns or hard mask patterns as an etch mask.

In the process of forming the plurality of patterns 103 by patterning the thin film, contaminants may be generated. In this disclosure, the contaminants are removed by using plasma in a cleaning process. Accordingly, collapse of the patterns as may result from the surface tension of a cleaning agent can be reduced or eliminated.

Plasma is preferably generated using at least one of a capacitively coupled plasma (CCP) type plasma generation apparatus, an inductively coupled plasma (ICP) type plasma generation apparatus, and a microwave plasma type plasma generation apparatus.

The contaminants generated in the process of patterning the thin film may be a mixture of a material that can be removed through an oxidation reaction and a material that can be removed through a reduction reaction. In the disclosure, to simultaneously remove the contaminants composed of materials that can be removed an oxidation reaction and a reduction reaction as described above, the contaminants are removed by using plasma having both oxidative properties and reductive properties. Accordingly, the method described in the disclosure can improve efficiency of the cleaning process. H₂O plasma is a preferred plasma both having oxidative properties and reductive properties.

The contaminants may include a material of a fume state. The contaminants of a fume state preferably are removed by using H₂O plasma. In particular, where to remove the contaminants, a cleaning process is performed using gas or plasma other than H₂O plasma, other contaminants of a fume state can be generated because of the gas or plasma used in the cleaning process. Where a cleaning process is performed using gas or plasma other than H₂O plasma, it is preferred that another cleaning process using H₂O plasma be further performed. In the cleaning process for removing the contaminants of a fume state, a temperature in the range of 25° C. to 300° C. is preferably employed.

In the process of removing the contaminants by using H₂O plasma, at least one of O₂ gas, N₂ gas, and fluorine gas is preferably added to improve cleaning characteristics.

To simplify the process, the process of patterning the thin film and the process of removing the contaminants preferably are performed in-situ.

Referring to FIG. 2B, in the cleaning process according to an exemplary embodiment of the disclosure, a plasma having oxidative and reductive properties is used, rather than a liquid cleaning agent. Accordingly, the collapse of the patterns 103 during or after the cleaning process can be reduced or eliminated.

In accordance with this disclosure, contaminants generated in a process of patterning a thin film are removed using plasma having both oxidative and reductive properties. Accordingly, the collapse of patterns resulting from surface tension of a cleaning agent during a cleaning process can be avoided.

Furthermore, in this disclosure, contaminants generated in a process of patterning a thin film are removed using plasma having both oxidative and reductive properties. Accordingly, cleaning efficiency can be improved because contaminants that must be removed by an oxidation reaction and contaminants that must be removed by a reduction reaction are removed at the same time.

What is claimed is:

1. A method of manufacturing semiconductor devices, comprising:
forming a thin film over an underlying layer;
forming a plurality of patterns by patterning the thin film, whereby contaminants are generated; and
cleaning the contaminants using a plasma having both oxidative and reductive properties.

2. The method of claim 1, wherein the plasma is H₂O plasma.

3. The method of claim 1, wherein at least one of O₂ gas, N₂ gas, and fluorine gas is added during cleaning to improve cleaning characteristics.

4. The method of claim 1, comprising patterning the thin film and cleaning the contaminants in-situ.

5. The method of claim 1, comprising cleaning the contaminants at a temperature in a range of 25° C. to 300° C.

6. The method of claim 1, comprising generating the plasma using at least one of a capacitively coupled plasma (CCP) type plasma generation apparatus, an inductively coupled plasma (ICP) type plasma generation apparatus, and a microwave plasma type plasma generation apparatus.
